(19) United States
(12) Patent Application Publication
(10) Pub. No.: US 2009/0224259 A1
(43) Pub. Date: Sep. 10, 2009

(54) DISPLAY SUBSTRATE AND METHOD FOR MANUFACTURING THE SAME

(75) Inventors: Yang-Ho JUNG, Yongin-si (KR); Hoon KANG, Suwon-si (KR); Jae-Sung KIM, Yongin-si (KR); Hi-Kuk LEE, Yongin-si (KR)

Correspondence Address: H.C. PARK & ASSOCIATES, PLC, 8500 LEESBURG PIKE, SUITE 7500, VIENNA, VA, 22182, US

(73) Assignee: Samsung Electronics Co., Ltd., Suwon-si (KR)

(21) Appl. No.: 12/398,555

(22) Filed: Mar. 5, 2009

(30) Foreign Application Priority Data
Mar. 7, 2008 (KR) 10-2008-0021286

(51) Int. Cl. H01L 31/0216; H01L 21/04

(52) U.S. Cl. 257/72; 438/69; 438/674; 438/669; 257/E31.119; 257/E21.04

(57) ABSTRACT

A display substrate includes a gate wiring, a data wiring, a switching element, an organic layer, and a pixel electrode. The gate wiring contacts a first transparent conductive layer formed on the gate wiring. The data wiring crosses the gate wiring. The data wiring contacts a second transparent conductive layer formed on the data wiring. The switching element is connected to the gate and data wirings. The organic layer is formed on a base substrate having the switching element formed thereon. The organic layer has first and second trenches corresponding to the first and second transparent conductive layers, respectively. The pixel electrode is formed in a pixel area of the organic layer.

### CROSS REFERENCE TO RELATED APPLICATION

This application claims priority from and the benefit of Korean Patent Application No. 10-2008-0021286, filed on Mar. 7, 2008, which is hereby incorporated by reference for all purposes as if fully set forth herein.

### BACKGROUND OF THE INVENTION

1. Field of the Invention

The present invention relates to a display substrate and a method of manufacturing the display substrate. More particularly, the present invention relates to a display substrate used for a liquid crystal display (LCD) device and a method of manufacturing the display substrate.

2. Discussion of the Background

Generally, a liquid crystal display (LCD) panel includes an array substrate having a plurality of thin-film transistors (TFTs) arrayed thereon. The number of masks is controlled in accordance with a process of manufacturing the TFT. The array substrate may be formed using a first mask to form a gate electrode, a second mask to form a semiconductor pattern on the gate electrode, a third mask to form source and drain electrodes, a fourth mask to form a contact hole through which the drain electrode contacts a pixel electrode, and a fifth mask to form a pixel in each pixel area.

When the number of masks decreases, the cost of the masks used to manufacture the LCD panel decreases. Moreover, a photoresist coating process, an exposure process, a development process, and a stripping process in accordance with a thin-film deposition, an ashing process, and a photolithography process may be decreased. Thus, manufacturing costs of the LCD panel are decreased. Recently, a four-mask process has been developed, in which a patterning of the semiconductor pattern, the source electrode, and the drain electrode is performed using a single mask.

In an array substrate having a high aperture ratio structure, a thick organic layer may be formed between the TFT and the pixel electrode, and the pixel electrode may overlap the data wiring to expand a formation area of the pixel electrode. Accordingly, in an array substrate having an organic layer, a process to pattern the organic layer may be added, so that an additional mask may be required.

### SUMMARY OF THE INVENTION

The present invention provides a display substrate that may have a high aperture ratio and decreased manufacturing costs.

The present invention also provides a method of manufacturing the above-mentioned display substrate.

Additional features of the invention will be set forth in the description which follows, and in part will be apparent from the description, or may be learned by practice of the invention.

The present invention discloses a display substrate including a gate wiring, a data wiring, a switching element, an organic layer, and a pixel electrode. The gate wiring is disposed on a base substrate. The gate wiring contacts a first transparent conductive layer on the gate wiring. The data wiring crosses the gate wiring. The data wiring contacts a second transparent conductive layer on the data wiring. The switching element is connected to the gate wiring and the data wiring. The organic layer is disposed on the base substrate having the switching element thereon. The organic layer has a first trench corresponding to the first transparent conductive layer and a second trench corresponding to the second transparent conductive layer. The pixel electrode is disposed in a pixel area of the organic layer.

The present invention also discloses a method of manufacturing a display substrate including forming a transistor layer on a base substrate, which comprises a switching element connected to a gate wiring and a data wiring that cross each other. Then, an organic layer is formed on the transistor layer. Then, the organic layer is patterned to form a first trench on the gate wiring and a second trench on the data wiring. Then, an insulation layer of the first and second trenches is etched using the patterned organic layer as a mask to form a first trench hole and a second trench hole, respectively. Then, a transparent conductive material is deposited to form first and second transparent conductive layers that contact the gate wiring and the data wiring, respectively, through the first and second trench holes, and a plurality of pixel electrodes that are spaced apart from each other by the first and second trenches.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a plan view showing a display substrate according to a first exemplary embodiment (Embodiment 1)/

FIG. 2 is a cross-sectional view taken along lines I-I′, II-II′, and III-III′ of FIG. 1.

FIG. 3 is a cross-sectional view of a display substrate manufactured using a first mask.

FIG. 4 is a cross-sectional view of a display substrate manufactured using a second mask.

FIG. 5A and FIG. 5B are cross-sectional views of a display substrate manufactured using a third mask.

FIG. 6 is a plan view showing the third mask of FIG. 5A.

FIG. 7 is a cross-sectional view of a display substrate according to a second exemplary embodiment (Embodiment 2).

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to,” or “coupled to” another element or layer, it can be directly on, connected to, or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments of the present invention will be described in detail with reference to the accompanying drawings.

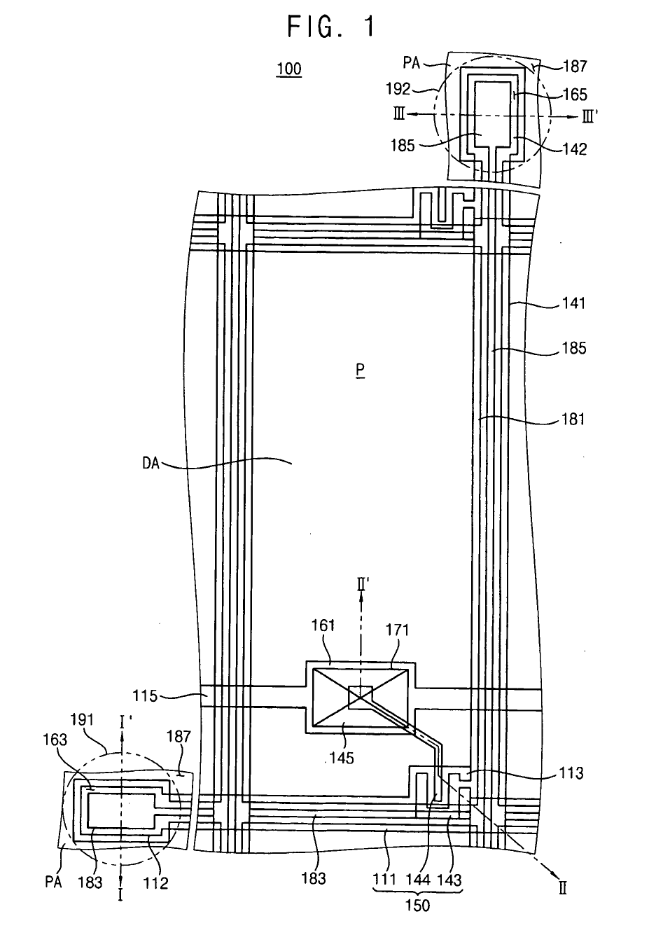

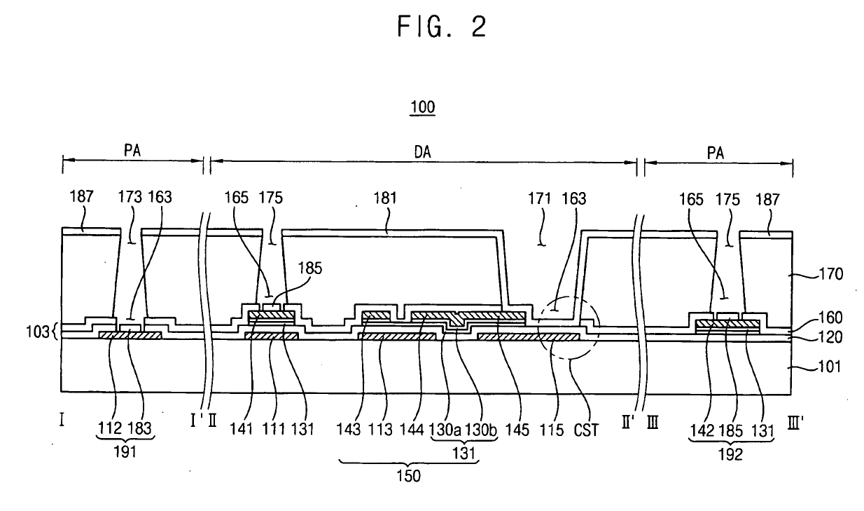

FIG. 1 is a plan view showing a display substrate according to Embodiment 1. FIG. 2 is a cross-sectional view taken along lines I-I′, II-II′, and III-III′ of FIG. 1.

Referring to FIG. 1 and FIG. 2, a display substrate 100 includes a base substrate 101, a transistor layer 103 formed on the base substrate 101, an organic layer 170 formed on the transistor layer 103, and a pixel electrode 181 formed on the organic layer 170.

The base substrate 101 includes a display area DA having the pixel electrode 181 formed thereon and a peripheral area PA surrounding the display area DA.

The transistor layer 103 of the display area DA includes a gate wiring 111, a storage electrode 115, a data wiring 141, a contact electrode 145, and a switching element 150, and a transistor layer 103 of the peripheral area PA includes a gate pad part 191 and a data pad part 192.

The gate wiring 111 extends in a first direction. A first transparent conductive layer 183 is formed on the gate wiring 111, which contacts the gate wiring 111. The storage electrode 115 is formed within the pixel area P and parallel to the gate wiring 111. The data wiring 141 extends in a second direction crossing the first direction. A second transparent conductive layer 185 is formed on the data wiring 141, which contacts the data wiring 141.

The switching element 150 includes a gate electrode 113 connected to the gate wiring 111, a semiconductor pattern 131 formed on the gate electrode 111, a source electrode 143 connected to the data wiring 141, and a drain electrode 144 spaced apart from the source electrode 143. The semiconductor pattern 131 includes an activation layer 130a and an ohmic contact layer 130b formed between the activation layer 130a doped with impurities and the source and drain electrodes 143 and 144.

The contact electrode 145 is connected to the drain electrode 144 to be connected to the pixel electrode 181. In this exemplary embodiment, the contact electrode 145 is formed in an area overlapping with the storage electrode 115. Alternatively, the contact electrode 145 may be formed in an area where the storage electrode 115 does not overlap the contact electrode 145.

As shown in FIG. 1 and FIG. 2, the display substrate 100 may be manufactured by a simplified process in which the semiconductor layer and the source metal layer are patterned using one mask, so that the semiconductor pattern 131 is formed below the source electrode 143, the drain electrode 144, and the data wiring 141, respectively.

The transistor layer 103 includes a gate insulation layer 120 formed on the gate electrode 113 and the storage wiring 115, and a protective insulation layer 160 formed on the source and drain electrodes 143 and 144.

The gate pad part 191 includes an edge portion 112 of the gate wiring 111 (hereinafter, a gate end portion) and the first transparent conductive layer 183 formed on the gate end portion 112 to contact the gate end portion 112. The data pad part 192 includes an edge portion 142 of the data wiring 141 (hereinafter, a data end portion) and the second transparent conductive layer 185 formed on the data end portion 142 to contact the data end portion 142.

The organic layer 170 may be formed on the transistor layer 103 to have a thickness of about 2 μm to about 4 μm. An opening 171 of a forward-tapered shape is formed through the organic layer 170 and corresponds to an area where the contact electrode 145 and the storage electrode 115 are formed. A storage capacitor CST is formed in the opening 171.

Moreover, a first trench 173 is formed through the organic layer 170 to correspond to the gate wiring 111 and the gate end portion 112, and a second trench 175 is formed through the organic layer 170 to correspond to the data wring 141 and the data end portion 142. The first and second trenches 173 and 175 may have a reverse-tapered shape. That is, the first and second trenches 173 and 175 expose the first and second transparent conductive layers 183 and 185, respectively.

A transparent conductive layer 187 is formed on the organic layer 170. For example, a pixel electrode 181 is formed in the display area DA, and a third transparent conductive layer 187 is formed in the peripheral area PA. Although not shown in FIG. 1 and FIG. 2, the transparent conductive layer 187 formed in the peripheral area PA may be spaced apart from a pixel electrode formed in a peripheral area of the display area DA.

The pixel electrode 181 is formed in the pixel area P, and an end portion of the pixel electrode 181 overlaps the gate wiring 111 and the data wiring 141 to create a high aperture ratio. Moreover, the pixel electrode 181 contacts the contact electrode 145 through a contact hole 161 in the protective insulation layer 160. Further, the protective insulation layer 160 corresponding to the opening 171 is removed, so that a storage capacitor CST, which is defined by the pixel electrode 181, the gate insulation layer 120, and the storage electrode 115, is formed.

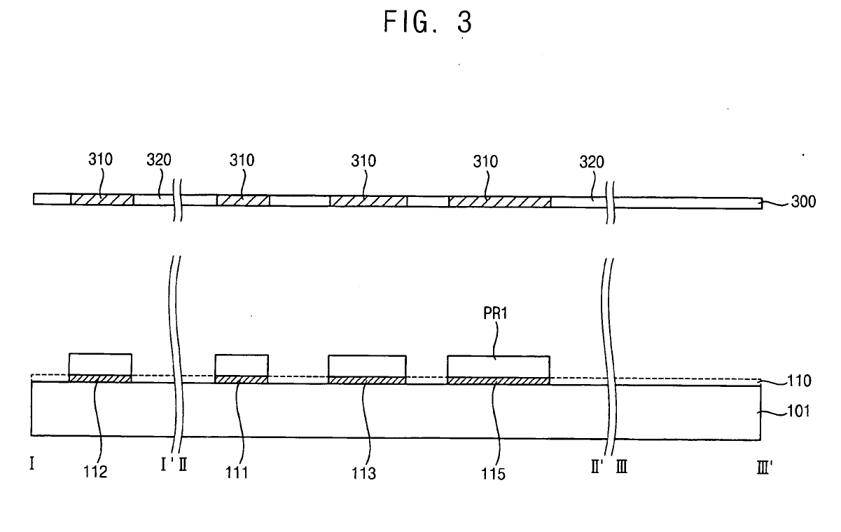

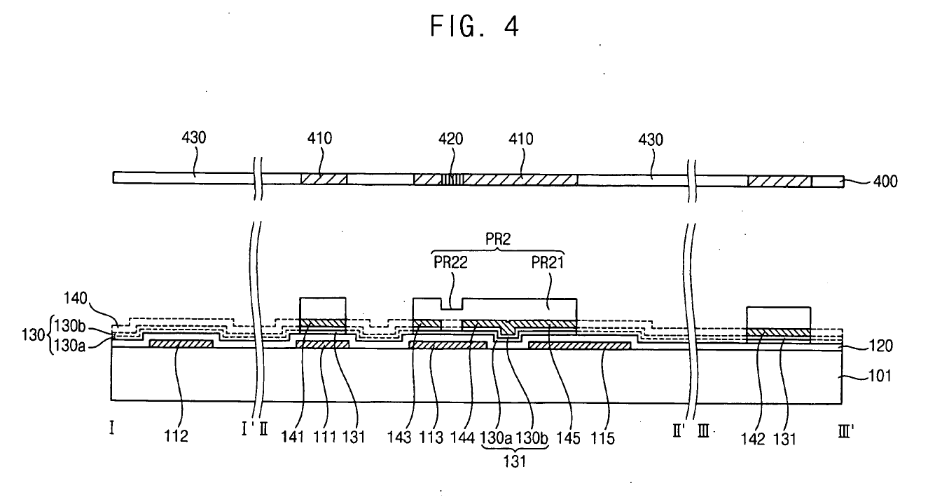

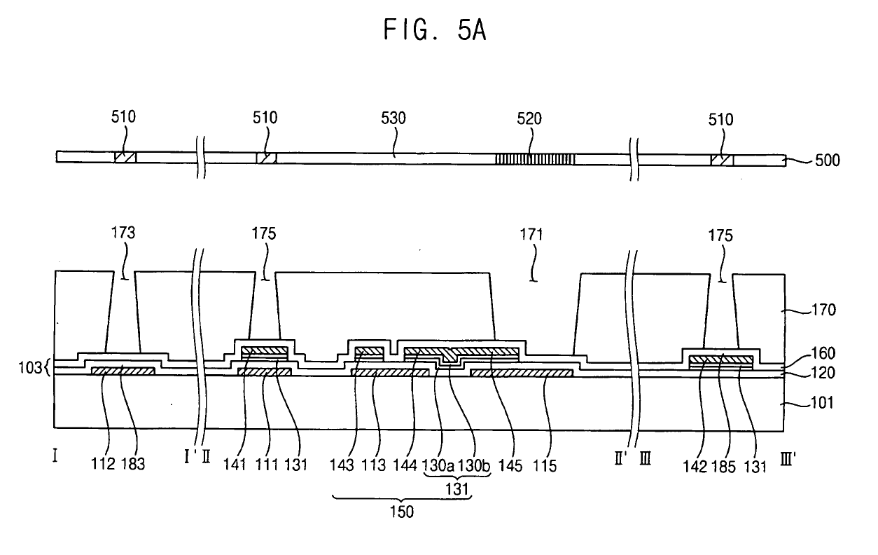

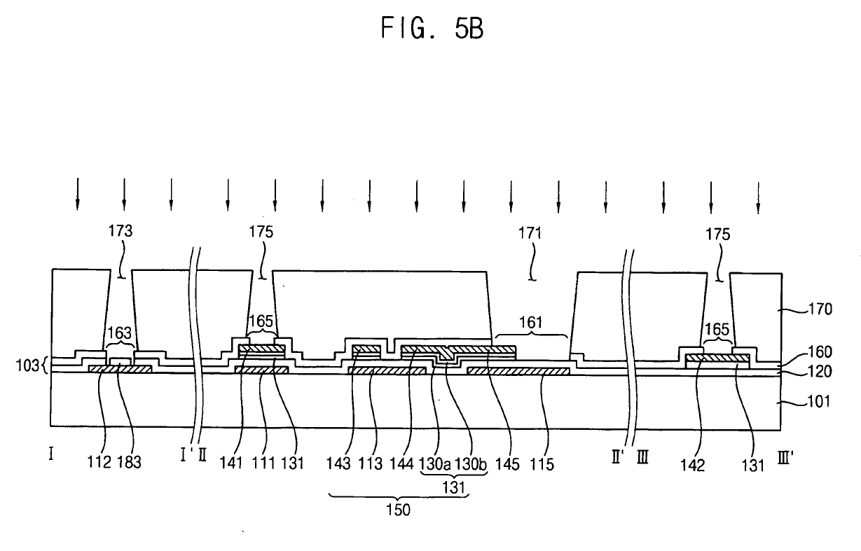

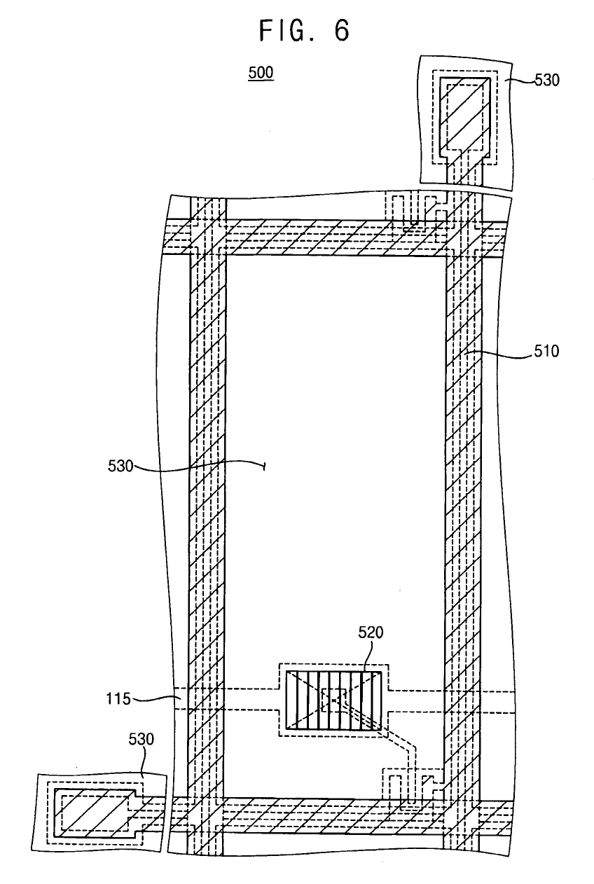

Hereinafter, a method of manufacturing a display substrate of FIG. 1 will be described with reference to FIG. 3, FIG. 4, FIG. 5, and FIG. 6.

FIG. 3 is a cross-sectional view of a display substrate manufactured using a first mask. Referring to FIG. 1 and FIG. 3, a gate metal layer 110 is formed on the base substrate 101. A first photoresist pattern PR1 is formed on the base substrate 101 having the gate metal layer 110 formed thereon by using a first mask 300 having a light-blocking portion 310 and a light-transmitting portion 320 formed thereon. The first photoresist pattern PR1 is formed in correspondence with the gate wiring 111, the gate end portion 112, the gate electrode 113, and the storage electrode 115. Then, the gate metal layer 110 is patterned using the first photoresist pattern PR1 to form a gate metal pattern on the base substrate 101. The gate metal pattern includes the gate wiring 111, the gate end portion 112, the gate electrode 113, and the storage electrode 115.

FIG. 4 is a cross-sectional view of a display substrate manufactured using a second mask. Referring to FIG. 1 and FIG. 4, the gate insulation layer 120 is formed on the base substrate 101 having the gate metal pattern formed thereon.

A semiconductor layer 130 and a source metal layer 140 are sequentially formed on the gate insulation layer 120. The semiconductor layer 130 includes an activation layer 130a doped with impurities and an ohmic contact layer 130b.

A second photoresist pattern PR2 is formed on the base substrate 101 having the source metal layer 140 using a second mask 400 having a light-blocking portion 410, a slit portion 420 and a light-transmitting portion 430 formed thereon. The second photoresist pattern PR2 is formed in correspondence with the data wiring 141, the data end portion 142, the source electrode 143, the drain electrode 144, and the contact electrode 145. For example, a first photo pattern PR21 of a first thickness is formed in correspondence with the data wiring 141, the data end portion 142, the source electrode 143, the drain electrode 144, and the contact electrode 145. The slit portion 420 is in an interval area between the source electrode 144 and the drain electrode 145, so that a second photo pattern PR22 of a second thickness, which is less than the first thickness, is formed in the interval area.

The semiconductor layer 130 and the source metal layer 140 are patterned using the second photoresist pattern PR2 to form a source metal pattern under which the semiconductor pattern 131 is formed. The source metal pattern includes the data wiring 141, the data end portion 142, the source electrode 143, the drain electrode 144, and the contact electrode 145.

FIG. 5A and FIG. 5B are cross-sectional views of a display substrate manufactured using a third mask. FIG. 6 is a plan view showing the third mask of FIG. 5A.

Referring to FIG. 1, FIG. 5A, and FIG. 6, the protective insulation layer 160 is formed on the base substrate 101 having the source metal pattern formed thereon. Thus, the transistor layer 103 is completed on the base substrate 101.

The organic layer 170 may be formed on the transistor layer 103 to have a thickness of about 2 μm to about 4 μm. The organic layer 170 may a negative-type photosensitive material in which an exposed portion is cured so that the exposed portion remains. A third mask 500 is disposed on the base substrate 101 having the organic layer 170 formed thereon.

The third mask 500 has a light-blocking portion 510 blocking light, a slit portion 520 diffracting light, and a light-transmitting portion 530 transmitting light. The light-blocking portion 510 is disposed in an area where the organic layer 170 is removed. For example, the light-blocking portion 510 is disposed in correspondence with the gate wiring 111, the gate end portion 112, the data wiring 141, and the data end portion 142.

The slit portion 520 is disposed in an area where the contact electrode 145 and the storage electrode 115 are formed. The light-transmitting portion 530 is disposed in an area where the organic layer 170 remains.

The organic layer 170 is patterned using the third mask 500. As the organic layer 170 includes the negative-type photosensitive material, an opening 171 of a forward-tapered shape is formed to correspond to the slit portion 520. Moreover, the first and second trenches 173 and 175 of a reverse-tapered shape are formed through the organic layer 170 by the light-blocking portion 510. The opening 171 of the forward-tapered shape and the first and second trenches 173 and 175 of the reversed tapered shape may be simultaneously formed by adjusting the slit portion 520 of the first mask 500, an exposure amount of the organic layer 170, an exposure time, and a baking process.

The opening 171 exposes the protective insulation layer 160 on the contact electrode 145 and the storage electrode 115. The first trench 173 exposes the protective insulation layer 160 on the gate wiring 111 and the gate end portion 112. The second trench 175 exposes the protective insulation layer 160 on the data wiring 141 and the data end portion 142. The first and second trenches 173 and 175 are respectively formed on the gate wiring 111 and the data wiring 141 along a direction in which the gate wiring 111 and the data wiring 141 extend, when viewed from a plan view.

Referring to FIG. 1 and FIG. 5B, the protective insulation layer 160 and portions of the gate insulation layer 120 are removed through a dry etching method using the organic layer 170 as a mask, which has the opening 171 and the first and second trenches 173 and 175 formed therein. For example, the protective insulation layer 160 exposed by the opening 171 is etched through an anisotropic dry etching method to expose the contact electrode 145 and the gate insulation layer 120. The protective insulation layer 160 exposed by the first trench 173 and the gate insulation layer 120 formed below the protective insulation layer 160 are etched to form a first trench hole 163. The protective insulation layer 160 exposed by the second trench 175 is etched to form a second trench hole 165.

Then, a transparent conductive material is deposited on the base substrate 101 having the contact hole 161 and the first and second trench holes 163 and 165 formed therein. Here, the transparent conductive material is formed along a surface profile of the organic layer 170, and pixel electrodes 181 spaced apart from each other are formed in pixel areas adjacent to the first and second trenches 173 and 175 having the reverse-tapered shape.

The transparent conductive material is deposited within the first and second trench holes 163 and 165 to form the first transparent conductive layer 183 and the second transparent conductive layer 185, respectively. In the opening 171 having the forward-tapered shape, the pixel electrode 181 contacts the contact electrode 145, which exposed by the opening 171. Moreover, the pixel electrode 181 contacts the gate insulation layer 120 on the storage electrode 115 to form the storage capacitor CST.

A third transparent conductive layer 187 is formed in the peripheral area PA, which is spaced apart from the first and second transparent conductive layers 183 and 185 of the gate and data pad parts 191 and 192.

Because the first transparent conductive layer 183 contacts the gate wiring 111, a formation of a parasitic capacitor may be prevented. Because the second transparent conductive layer 185 contacts the data wiring 141, a formation of a parasitic capacitor may be prevented.

The pixel electrodes 181 may be formed to be spaced apart from the pixel areas along a pattern profile of the organic layer 170. Therefore, a conventional patterning process of a pixel electrode may be removed, so that a manufacturing process may be simplified.

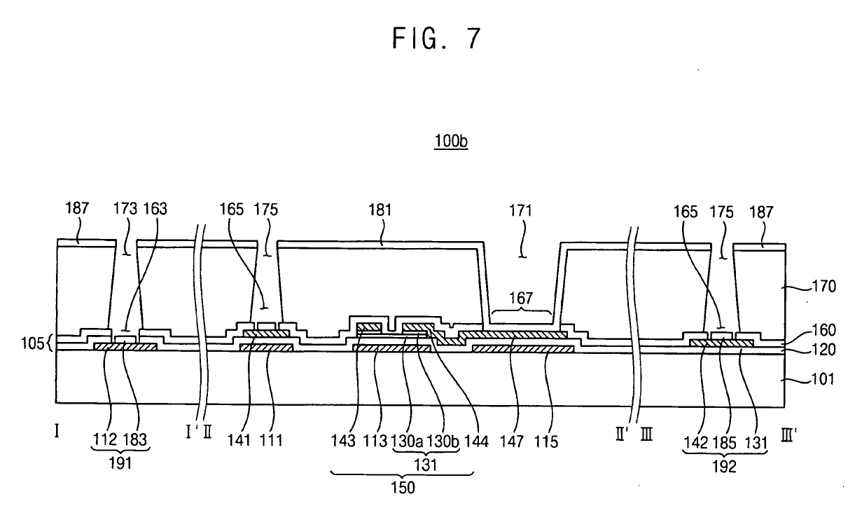

FIG. 7 is a cross-sectional view of a display substrate according to Embodiment 2.

Referring to FIG. 1 and FIG. 7, a display substrate 100b includes a base substrate 101, a transistor layer 105 formed on the base substrate 101, an organic layer 170 formed on the transistor layer 105, and a pixel electrode 181 formed on the organic layer 170.

The transistor layer 105 of the display area DA includes a gate wiring 111, a storage electrode 115, a data wiring 141, a contact electrode 147, and a switching element 150, and the transistor layer 105 of the peripheral area PA includes a gate pad part 191 and a data pad part 192. The switching element 150 includes a gate electrode 113 connected to the gate wiring 111, a source electrode 143 connected to the data wiring 141, and a drain electrode 144 spaced apart from the source electrode 143. The switching element 150 further includes a semiconductor pattern 132 formed below the source and drain electrodes 143 and 144.

As the semiconductor layer and the source metal layer are patterned using the different masks at the display substrate 100b, the semiconductor pattern 132 is not formed below the data wiring 141 and the contact electrode 147. The size of the contact electrode 147 is substantially the same as that of the storage electrode 115 in an area where the storage electrode 115 is formed.

The pixel electrode 181 contacts the contact electrode 147 through the contact hole 167. Therefore, the pixel electrode 181 is connected to the switching element 150, and the storage capacitor CST is defined by the contact electrode 147, the gate insulation layer 120, and the storage electrode 115.

A method of manufacturing a display substrate of FIG. 7 will be described in detail with reference to FIG. 3, FIG. 4, FIG. 5A, FIG. 5B, FIG. 6, and FIG. 7.

Referring to FIG. 3 and FIG. 7, a gate metal pattern including the gate wiring 111, the gate end portion 112, the gate electrode 113, and the storage electrode 115 is formed on the base substrate 101 using the first mask 300.

Referring to FIG. 4 and FIG. 7, the semiconductor layer 130 including the active layer 130a and the ohmic contact layer 130b is formed on the base substrate 101 having the gate insulation layer 120 formed thereon. Then, the semiconductor layer 130 is patterned using a mask (not shown) to form a semiconductor pattern 132 on the gate electrode 113.

Then, the source metal layer 140 is formed on the base substrate 101 having the semiconductor pattern 132 formed thereon. The source metal layer 140 is patterned using a second mask 400 having the slit portion 420 and the transmitting portion 430 formed thereon. A source metal pattern is formed on the base substrate 101, which includes the data wiring 141, the data end portion 142, the source electrode 143, the drain electrode 144, and the contact electrode 147.

Referring to FIG. 5A, FIG. 6, and FIG. 7, a protective insulation layer 160 is formed on the base substrate 101 having the source metal pattern. Thus, the transistor layer 105 is completed on the base substrate 101.

A negative-type photosensitive organic layer 170 is formed on the transistor layer 105. The organic layer 170 is patterned using the third mask 500 to form an opening 171 having a forward-tapered shape and first and second trenches 173 and 175 of a reverse-tapered shape.

The opening 171 exposes the protective insulation layer 160 on the contact electrode 147. The first trench 173 exposes the protective insulation layer 160 on the gate wiring 111 and the gate end portion 112. The second trench 175 exposes the protective insulation layer 160 on the data wiring 141 and the data end portion 142.

Referring to FIG. 5B and FIG. 7, the protective insulation layer 160 and the gate insulation layer 120 are removed through a dry etching method using the organic layer 170 having the opening 171 and the first and second trenches 173 and 175 formed thereon as a mask. For example, the protective insulation layer 160 exposed by the opening 171 is etched through an anisotropic dry etching method to form a contact hole 167 exposing the contact electrode 147. The first trench hole 163 is formed within the first trench 173, and the second trench hole 165 is formed within the second trench 175.

Then, a transparent conductive material is deposited on the base substrate 101 having the contact hole 167 and the first and second trench holes 163 and 165 formed thereon. Pixel electrodes 181 spaced apart from each other are formed in pixel areas adjacent to the first and second trenches 173 and 175 having the reverse-tapered shape. The first transparent conductive layer 183 and the second transparent conductive layer 185 are formed within the trench hole 163 and the second trench hole 165, respectively.

Because the first and second transparent conductive layers 183 and 185 contacts the gate wiring 111 and the data wiring 141, respectively, a formation of a parasitic capacitor may be prevented. The pixel electrodes 181 may be spaced apart from the pixel areas along a pattern profile of the organic layer 170. Therefore, a conventional patterning process of a pixel electrode may be removed, so that a manufacturing process may be simplified.

According to the exemplary embodiments of the present invention, a profile of a patterned negative-type organic layer is used in a manufacturing process of a display substrate, so that a patterning process of a pixel electrode may be removed, and thus a manufacturing process may be simplified. The organic layer is used for the display substrate, so that a display substrate of a high aperture ratio may be obtained.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A display substrate, comprising:
a gate wiring disposed on a base substrate, the gate wiring contacting a first transparent conductive layer on the gate wiring;
a data wiring crossing the gate wiring, the data wiring contacting a second transparent conductive layer on the data wiring;
a switching element connected to the gate wiring and the data wiring;
an organic layer disposed on the base substrate having the switching element formed thereon, the organic layer comprising a first trench corresponding to the first transparent conductive layer and a second trench corresponding to the second transparent conductive layer; and
a pixel electrode disposed in a pixel area of the organic layer.

2. The display substrate of claim 1, wherein an end portion of the pixel electrode overlaps with the data wiring.

3. The display substrate of claim 1, wherein the organic layer further comprises a first opening corresponding to a contact electrode that is connected to a drain electrode of the switching element.

4. The display substrate of claim 3, wherein the first trench and the second trench each have a reverse-tapered shape, and the first opening has a forward-tapered shape.

5. The display substrate of claim 1, further comprising a storage electrode within the pixel area,
wherein the organic layer further comprises a first opening corresponding to the storage electrode.

6. The display substrate of claim 5, wherein the first opening has a forward-tapered shape.

7. A method of manufacturing a display substrate, the method comprising:
forming a transistor layer comprising a switching element connected to a gate wiring and a data wiring that cross each other on a base substrate;
forming an organic layer on the transistor layer;
patterning the organic layer to form a first trench on the gate wiring and a second trench on the data wiring;
etching an insulation layer of the first trench and the second trench using the patterned organic layer as a mask to form a first trench hole and a second trench hole, respectively; and
depositing a transparent conductive material to form a first transparent conductive layer and a second transparent conductive layer that contact the gate wiring and the data wiring, respectively, through the first trench hole and the second trench hole, and a plurality of pixel electrodes that are spaced apart from each other by the first trench and the second trench.

8. The method of claim 7, wherein forming the first trench hole and the second trench hole comprises etching the insulation layer through an anisotropic dry etching method.

9. The method of claim 7, wherein the organic layer comprises a negative-type photosensitive material.

10. The method of claim 7, wherein patterning the organic layer further comprises forming a first opening on a contact electrode that is connected to a drain electrode of the switching element.

11. The method of claim 10, wherein patterning the organic layer is performed using a mask comprising a slit portion and a light-blocking portion, the slit portion diffracting light at a position corresponding to the first opening, and the light-blocking portion blocking light at a position corresponding to the first trench and at a position corresponding to the second trench.

12. The method of claim 11, wherein the first trench and the second trench have a reverse-tapered shape, and the first opening has a forward-tapered shape.

13. The method of claim 12, wherein forming the first trench hole and the second trench hole comprises:
etching a gate insulation layer and a protective insulation layer on the gate wiring to form the first trench hole exposing the gate wiring; and
etching the protective insulation layer on the data wiring to form the second trench hole exposing the data wiring.

14. The method of claim 13, wherein forming the first trench hole and the second trench hole further comprises:
etching the protective insulation layer on the contact electrode to form a contact hole exposing the contact electrode.

15. The method of claim 7, wherein forming a transistor layer further comprises forming a storage electrode within a pixel area where the pixel electrode is formed.

16. The method of claim 15, wherein patterning the organic layer further comprises forming a first opening having a forward-tapered shape to correspond to an area where the storage electrode is formed.

17. The method of claim 16, further comprising:
etching a protective insulation layer within the first opening to expose a gate insulation layer on the storage electrode.

18. The method of claim 17, wherein the pixel electrode contacts the gate insulation layer on the exposed storage electrode.

19. The method of claim 7, wherein forming the transistor layer comprises:
patterning a gate metal layer on the base substrate to form a gate metal pattern comprising a gate wiring and a gate electrode;
forming a gate metal insulation layer on the base substrate having the gate metal pattern formed thereon;
patterning a semiconductor layer and a source metal layer formed on a base substrate having the gate insulation layer formed thereon using one mask, to form a source metal pattern having a data wiring, a source electrode, a drain electrode, and a contact electrode; and
forming a protective insulation layer on a base substrate having the source metal pattern formed thereon.

20. The method of claim 7, wherein forming the transistor layer comprises:
patterning a gate metal layer on the base substrate to form a gate metal pattern comprising a gate wiring and a gate electrode;
forming a gate insulation layer and a semiconductor layer on a base substrate having the gate metal pattern formed thereon;
patterning the semiconductor layer to form a semiconductor pattern on the gate electrode;
patterning a source metal layer on a base substrate having the semiconductor pattern formed thereon to form a source metal pattern comprising a data wiring, a source electrode, a drain electrode, and a contact electrode; and
forming a protective insulation layer on a base substrate having the source metal pattern formed thereon.
